(19) United States
(12) Patent Application Publication
(10) Pub. No.: US 2010/0240224 A1
(43) Pub. Date: Sep. 23, 2010

(54) MULTI-ZONE SEMICONDUCTOR FURNACE

(75) Inventors: Hsin-Hsien Wu, Hsinchu City (TW); Chun-Lin Chang, Jhubei City (TW); Chi-Ming Yang, Hsin-San District (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufactruing Co., Ltd., Hsin-Chu (TW)

(21) Appl. No.: 12/408,427

(22) Filed: Mar. 20, 2009

(51) Int. Cl. H01L 21/26; F27D 11/00

(52) U.S. Cl. 438/765; 219/390; 257/E21.328

(57) ABSTRACT

A semiconductor furnace suitable for chemical vapor deposition processing of wafers. The furnace includes a thermal reaction chamber having a top, a bottom, a sidewall, and an internal cavity for removably holding a batch of vertically stacked wafers. A heating system is provided that includes a plurality of heaters arranged and operative to heat the chamber. The heating system includes at least one top heater; at least one bottom heater, and a plurality of sidewall heaters spaced along the height of the reaction chamber to control temperature variations within in the chamber and promote uniform film deposit thickness on the wafers.

### FIELD OF THE INVENTION

The present invention generally relates to semiconductors, and more particularly to heating systems used in semiconductor furnaces for wafer processing.

### BACKGROUND

Some processing steps used in fabricating semiconductors include oxidation, diffusion, doping, annealing, and chemical vapor deposition (CVD). These processes are typically performed at elevated temperatures within heated controlled environments. CVD is a reactive process used to produce or deposit thin films of material on the wafer including without limitation metals, silicon dioxide, tungsten, silicon nitride, silicon oxynitride, and various dielectrics. The CVD process entails placing a wafer or plurality of wafers in a heated or thermal reaction chamber and introducing one or more reactant gases into the chamber. The gases contain with various chemical precursors (e.g. silane and nitrogen to form a silicon nitride film) that react at the heated wafer surface to form a thin film of the desired semiconductor material and thickness thereon. The uniformity of the film deposited on the wafer by CVD is affected and controlled by regulating and attempting to optimize CVD process parameters such temperature of the wafer, reaction chamber pressure, flow path and rate of reactant gases, and deposition time or duration.

One type of heated or thermal reaction chamber used in CVD processes are vertical semiconductor furnaces. These vertical furnaces are capable of holding a plurality of vertically-stacked semiconductor wafers which undergo CVD batch processing simultaneously. The vertical furnaces include a thermal reaction vessel or chamber which may be loaded with multiple wafers that in some embodiments are held in a vertically-stackable rack referred to in the art as a wafer ladder or boat. The wafer boat comprises a frame having multiple horizontal slots which each hold an individual wafer in spaced-apart, stacked vertical relationship to the other wafers. The wafer boats may typically hold from approximately 100-125 wafers. Vertical space is provided between the wafers to allow the CVD reactant gases to circulate therethrough for forming the desired material film deposits on top of the wafers. The thermal reaction chambers are commonly cylindrical in shape (also referred to as reaction tubes) and generally have a closed top and open bottom to allow for insertion of the wafer boats holding the vertical wafer stacks.

Some examples of conventional vertical semiconductor furnaces and associated appurtenances are shown in U.S. Pat. Nos. 6,538,237; 6,435,865; 6,187,102; 6,031,205; and 7,241,701; all of which are incorporated herein by reference in their entireties.

The vertical semiconductor furnaces include a heat source, which in some embodiments may include resistance type heaters, radiant type heaters, or a combination thereof. Examples of resistance type heaters include electric resistive wire coil elements or similar. Some examples of radiant type heaters include heating lamps or quartz-heating elements. The heaters are typically disposed outside but proximate to the quartz reaction chamber to heat the chamber and increase its internal temperature.

In order to improve manufacturing efficiencies and reduce production costs, wafer sizes have steadily increased over the years. Standard silicon wafer sizes have steadily grown from about 200 mm (about 8 inches diameter) to 300 mm (about 12 inches diameter). The next generation wafer standard has been set for 450 mm (about 18 inches in diameter). The next generation wafer size of 450 mm has created a challenge in maintaining a uniform temperature in the vertical wafer stacks throughout the wafer boat during the CVD process that is desired to promote uniform material film deposition on each wafer's surface.

Existing heater arrangements used in CVD thermal reaction chambers have proven to be inadequate to provide the needed uniformity in temperature for maintaining the desired consistency in both material film thickness deposited over the entire surface of each individual wafer, and from wafer-to-wafer throughout the entire batch or stack of wafers being processed for the larger next generation wafer sizes. Ideally, each wafer in the entire batch of wafers undergoing CVD in the thermal reaction chamber should have a uniform film thickness in order to meet acceptable process thickness variation tolerances on an individual wafer and wafer-to-wafer basis. Some existing heater arrangements used for traditionally smaller 200-300 mm diameter wafers do not provide the necessary temperature control and uniformity to maintain the desired tolerances for 450 mm wafers. Horizontal temperature variation between the edges and center of the wafers cause generally unacceptable variances in layer thicknesses deposited on each wafer. Temperatures at the wafer center are typically lower than at the edges. Vertical temperature variations in the stack of wafers held by the wafer boat cause generally unacceptable variances in layer thicknesses deposited from wafer-to-wafer in the stack.

An improved heater arrangement for vertical semiconductor furnaces is desired to meet the challenges of the next generation wafer size.

### SUMMARY

According to one embodiment, a semiconductor furnace suitable for chemical vapor deposition wafer processing includes: a vertical thermal reaction chamber having a height, a top, a bottom, a sidewall, and an internal cavity for removably holding a batch of wafers; a wafer boat positioned in the reaction chamber and being configured and adapted to hold a plurality of wafers in vertically-stacked relationship; and a heating system comprising a plurality of heaters arranged and operative to heat the chamber. The heating system includes at least one top heater, at least one bottom heater, and a plurality of sidewall heaters distributed and spaced along the height of the reaction chamber. The sidewall heaters are preferably arranged such that at least one sidewall heater is provided for every ten wafers or less than ten wafers to promote uniform thickness of film deposited on the wafers. Advantageously, the foregoing heater arrangement promotes uniform wafer thickness on each wafer and from wafer-to-wafer in each batch processed in the furnace.

According to another embodiment, a combination semiconductor furnace adapted for chemical vapor deposition processing and plurality of wafers processed therein includes: a vertical thermal reaction chamber having a height, a top, a bottom, a sidewall, and an internal cavity for removably holding a batch of wafers; a wafer boat positioned in the reaction chamber and holding a plurality of wafers in vertically-stacked relationship; and a heating system comprising a plurality of heaters arranged and operative to heat the chamber that includes at least one top heater, at least one bottom heater, and a plurality of sidewall heaters distributed and spaced along the height of the reaction chamber. The sidewall heaters are preferably arranged such that at least one sidewall heater is provided for every ten vertically-stacked wafers to promote uniform thickness of film deposited on the wafers. The combination further includes a plurality of wafers each having a diameter of at least 450 mm; the wafers undergoing chemical vapor deposition processing in the reaction chamber. The resultant film of material deposited on each wafer preferably has a maximum variation in thickness on each wafer that is not more than 1.5%. In another embodiment, the resultant film of material deposited on each wafer has a maximum wafer-to-wafer variation in thickness that is less than 0.5%.

According to another embodiment, a method for forming a thin layer of material on a semiconductor wafer using chemical vapor deposition includes: providing a semiconductor furnace including a vertical thermal reaction chamber having a height, a top, an open bottom, a sidewall, and an internal cavity for removably holding a batch of wafers, the semiconductor furnace further including a heating system comprising at least one top heater, at least one bottom heater, and a plurality of sidewall heaters distributed and spaced along the height of the reaction chamber, the sidewall heaters being arranged such that at least one sidewall heater is provided for every ten vertically-stacked wafers to promote uniform thickness of film deposited on the wafers; inserting a wafer boat holding a plurality of vertically-stacked wafers into the reaction chamber; heating the reaction chamber with the heating system; introducing a precursor reactant gas into the reaction chamber; and forming a film of material on each wafer via chemical vapor deposition.

### BRIEF DESCRIPTION OF THE DRAWINGS

The features of the preferred embodiments will be described with reference to the following drawings where like elements are labeled similarly, and in which:

FIG. 1 is a schematic cross-sectional side view of a first existing heater arrangement for a semiconductor furnace;

FIG. 2 is a schematic cross-sectional side view of a second existing heater arrangement for a semiconductor furnace;

FIG. 3 is a schematic cross-sectional side view diagram of a heater arrangement for a semiconductor furnace according to one embodiment of the present invention;

FIG. 4 is a cross-sectional side view of a of one possible embodiment of a semiconductor furnace and heater arrangement of FIG. 3; and

FIG. 5 is a top view of a sidewall heaters shown in FIG. 3.

All drawings are schematic and are not drawn to scale.

### DETAILED DESCRIPTION

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present invention. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combination of features that may exist alone or in other combinations of features; the scope of the invention being defined by the claims appended hereto.

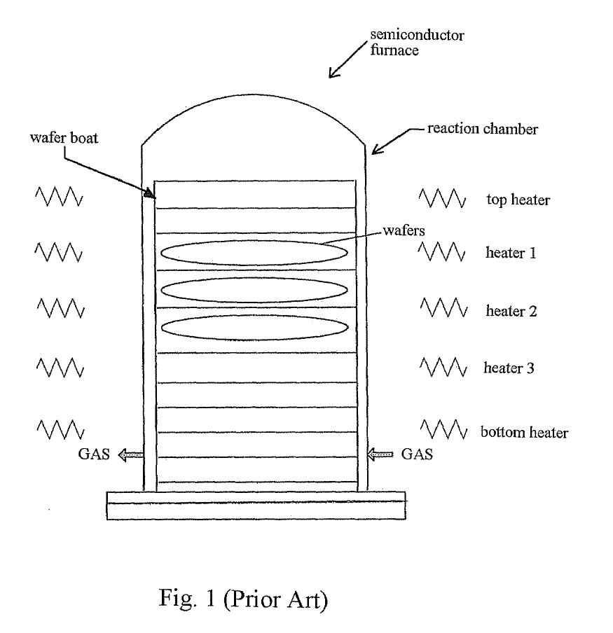

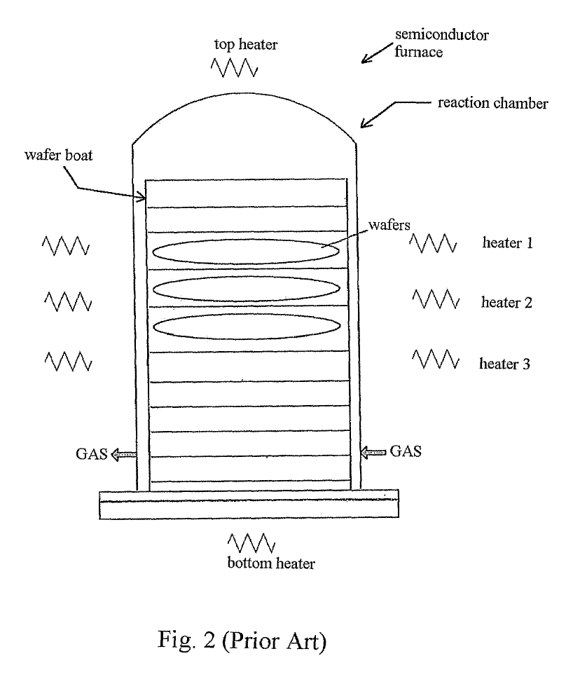

FIGS. 1 and 2 show schematic diagrams of two conventional heater arrangements used for semiconductor furnaces that process traditional wafer sizes of 300 mm or less. In FIG. 1, there are five sidewall heater zones provided at the sidewall of the CVD reaction chamber. Each heater zone is defined by and includes a heater, which in some embodiments is an electric resistance type heater coil or element. An alternative conventional heater arrangement shown in FIG. 2 includes three sidewall heater zones provided at the sidewall of reaction chamber, one top heater zone, and one bottom heater zone. Conventional electric or electronic heater controls are provided in both of the foregoing heater arrangements that allows the temperature output from each heater to be adjusted by varying the energy input from the electrical power source.

The sidewall heater zones are established for the existing heater arrangements shown in FIGS. 1 and 2 such that the heater-to-wafer ratio is approximately one heater controlling temperature for an average of 20-25 wafers. When either of these foregoing arrangements is used for CVD processing of the larger next generation 450 mm size wafers, however, the temperature profiles throughout the vertical stack of wafers cannot be adequately controlled (as discussed in the Background Section of the present application) through fine tuning and adjustment of each heater's energy output to deposit uniform material thicknesses sufficient to meet desired thickness variation criteria established for each wafer or from wafer-to-wafer.

When either of these foregoing existing heater arrangements are used for CVD processing of the larger next generation 450 mm size wafers, the temperature profiles throughout the vertical stack of wafers cannot be adequately controlled (as discussed in the Background Section of the present application) through fine tuning and adjustment of each heater's heat output alone to obtain the desired target temperature profiles throughout the reaction chamber or to deposit uniform material thicknesses sufficient to meet established thickness variation criteria for each wafer or from wafer-to-wafer. Therefore, dies on at least portions of each wafer may fail die stress and reliability testing resulting in higher than desired die reject rates.

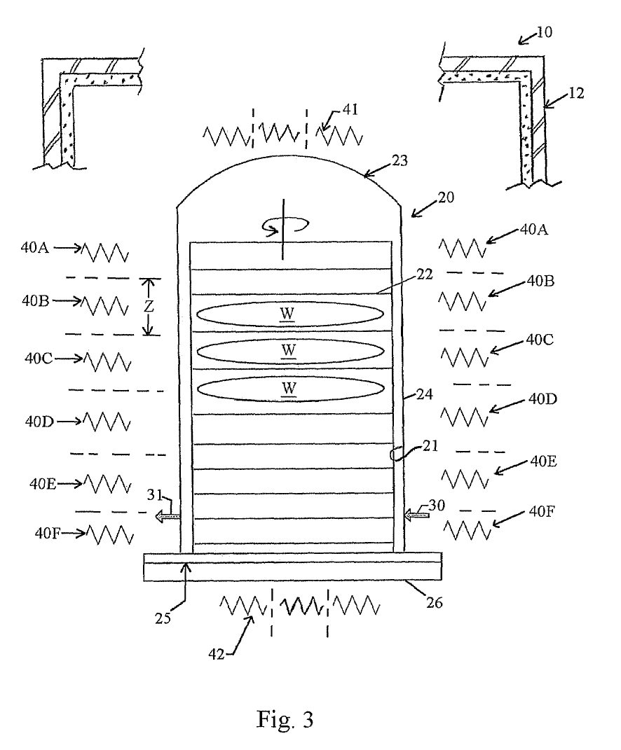

FIG. 3 is a schematic diagram of one embodiment of a semiconductor furnace 10 incorporating a CVD thermal reaction chamber 20 according to the present invention. Semiconductor furnace 10 may include a conventional insulated housing 12 (partially shown in FIG. 3) which is configured and adapted to provide a thermal enclosure around substantially all of reaction chamber 20 to establish a temperature controlled environment for reaction chamber 20. CVD reaction chamber 20 includes an internal cavity 21 defining a space for removably receiving a conventional wafer boat 22 that is configured and adapted for supporting and holding a plurality of vertically-stacked wafers W in a conventional manner. In one embodiment, reaction chamber 20 may have a closed top 23, sidewall 24, and open bottom 25 to allow the wafer boat 22 to be inserted and removed from the chamber for batch processing of wafers W. In one embodiment, wafer boat 22 comprises a conventional open-frame structure such as a ladder-type design having multiple horizontal slots for supporting the wafers W and allowing reactant gas to flow horizontally over the face of the wafers W to build the desired material film thicknesses thereon. Wafer boat 22 may be sized to hold 50-125 wafers W or more in some embodiments; however, any suitable number of wafers may be held by the wafer boat depending on the height of the reaction chamber 20 provided. Wafer boat 22 may be made of quartz, SiN, or any other suitable material commonly used in the art.

Typical vertical spacing of wafers W in wafer boat 22 may be about 6-10 mm apart in some embodiments.

Reaction chamber 20 may have a conventional cylindrical shape in one embodiment and may be made of quartz or any other suitable material commonly used, like for example without limitation SiC. Reaction chamber 20 may include a coating such as polysilicon or another coating material typically used depending on the type of process conducted in the chamber. Reaction chamber 20 may have any suitable height or length depending on the number of wafers to be processed in each batch. In some exemplary embodiments, reaction chamber 20 may have a representative vertical height or length of 100-150 cm; however, any suitable height or length may be provided. Reaction chamber 20 for processing 450 mm wafers must be sized to more than 450 mm diameter and a chamber length of about 50-150 cm in some embodiments.

A sealable and removable bottom closure lid 26 is provided which may be sealed to the bottom 25 of reaction chamber 20 to form a gas-tight chamber seal for processing the wafers W. In one embodiment, bottom 25 may be provided with a flange as shown for receiving lid 26. Bottom closure lid 26 may include a support structure to provide support for wafer boat 22 which may be attached to the lid in a conventional manner.

Other conventional appurtenances typically used in conjunction with CVD reaction chamber 20 processing assemblies and semiconductor furnaces may be provided. For example, reaction gas supply inlet connections 30 and outlet connections 31 may be furnished to allow one or more process gases to be introduced and removed from reaction chamber 20. Gas manifold and injectors, furnace cooling to allow quick changing of wafer batches, an external insulated housing enclosing the reaction chamber 20, wafer boat elevator or lift and robotically-controlled arm for positioning, raising, and lowering the wafer boat 22 into/from chamber 20, etc. (not shown). Some of these appurtenances which may be provided are described, for example, in U.S. Pat. Nos. 6,538,237; 6,435,865; 6,031,205; and 7,241,701; which are all incorporated herein by reference in their entireties.

In some embodiments, wafer boat 20 may be provided with a conventional motor drive mechanism (not shown) to allow the stack of wafers W to be rotated (see rotational arrow in FIG. 3) during the CVD process to promote uniform thickness of the layer of material deposited on the wafers.

The operation of semiconductor furnace 10 and batch processing of wafers W may be controlled by a suitable commercially-available temperature controllers as conventionally used in the art to regulate the heat output from the furnace heating system including temperature ramp up and ramp down rates.

With continuing reference to FIG. 3, semiconductor furnace 10 includes a plurality of heaters, which preferably are distributed along the sidewall 24, top 23, and bottom 25 of CVD reaction chamber 20. In one embodiment, the heaters include sidewall heaters 40A-40F, top heaters 41, and bottom heaters 42 as shown.

To provide better temperature control and uniform heat distribution throughout the reaction chamber 20 for CVD processing of next generation 450 mm diameter wafers, more than five sidewall heaters 40A-40F are preferably provided along the sidewall 24 of the reaction chamber 20 with each sidewall heater 40A-40F defining a heater zone Z as shown in FIG. 3. Preferably, each sidewall heater 40A-40F controls temperature for less than or equal to no more than ten (10) vertically-stacked wafers W per heater to provide better temperature uniformity and corresponding uniformity in wafer level thicknesses both on each wafer W (e.g. from center of wafer to edges thereof) and from wafer-to-wafer in the vertical stack of wafers W supported by the wafer boat 22. This arrangement therefore enhances the ability to control CVD process temperature profiles within the reaction chamber 20 close to the desired target profiles.

In some embodiments, the sidewall heaters 40A-40F and heater zones Z may be approximately evenly distributed along the vertical height of the reaction chamber with preferably each heater controlling temperature within a respective heater zone having no more than 10 vertically-stacked wafers W.

With continuing reference to FIG. 3, sidewall heaters 40A-40F in one embodiment may be electric resistance type heaters having controllable heat output which may be regulated by adjusting the energy input to each heater via a variable resistance control such as a rheostat or other suitable similar electrical control device. Sidewall heaters 40A-40F are preferably disposed proximate to the external sidewall 24 and are arranged in spaced vertical relationship to each other along the height of reaction chamber 20. Sidewall heaters 40A-40F therefore define a plurality of vertical heater zones Z within reaction chamber 20 with the temperature in each zone being controlled by a single heater 40A-40F.

The heat output from sidewall heaters 40A-40F may be fine tuned to adjust the temperature in each heater zone Z. The heat output from each sidewall heaters 40A-40F preferably is adjustable independent of the other sidewall heaters. The heat output setting of each sidewall heater may be adjusted either manually by a user or controlled automatically via a heater controller or computer in conjunction with control signals generated by temperature sensors disposed in the semiconductor furnace 10 and/or based on predetermined heater temperature output settings derived from experience and empirical data correlated with the size of wafer being processed and/or type of material film being deposited on the wafers W.

In one embodiment, sidewall heaters 40A-40F may be a conventional ring-shaped electric resistance coils or elements that each extend circumferentially around sidewall 22 for at least the majority of the outer circumference of reaction chamber 20. FIG. 3 diagrammatically shows the left and right portions of each ring-shaped sidewall heater 40A-40F. The resistance coil heaters are electrically coupled via conventional conductors to an electrical power supply, which may be routed through suitable conventional variable resistance electrical controls as typically used in the industry and described herein to allow the heat output (e.g. Btuh) to be adjusted from each heater 40A-40F.

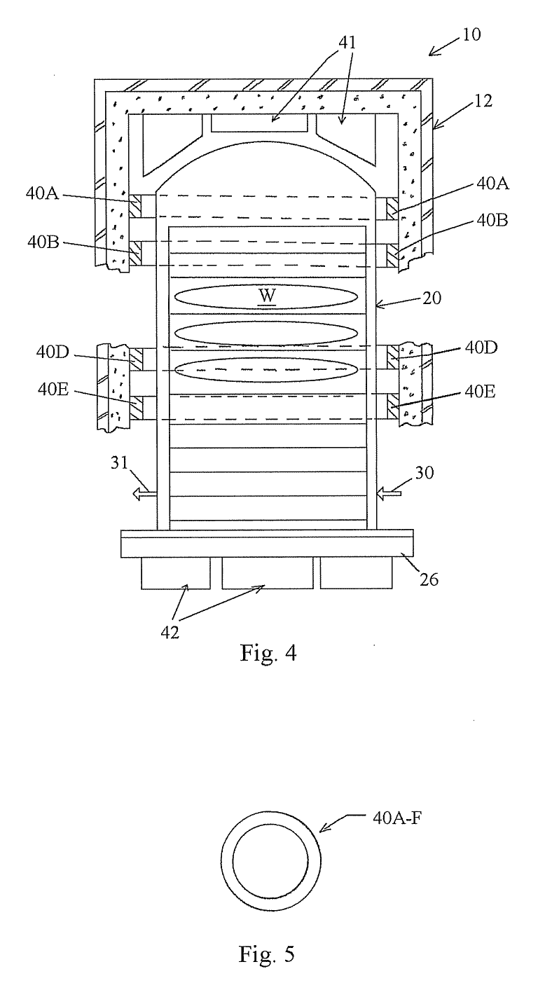

The electric resistance coils or elements comprising sidewall heaters 40A-40F may have any suitable cross-sectional shape such as circular, square, rectangular, etc. One possible embodiment of a rectangular cross-sectionals shaped sidewall heater 40A-40F is shown in FIG. 4. FIG. 4 shows a half-segment of some of the sidewall heaters 40A-40F. FIG. 5 shows a top view of sidewall heater 40A-40F.

Referring to FIG. 3, top heaters 41 may be a bulk-shaped electric resistance coils or elements and the heater shape may be varied based on temperature requirements and shape and/or size of reaction chamber 20. Preferably, at least two top heaters 41 and more preferably at least three top heaters are provided to uniform CVD process temperatures in the bottom portion of the reaction chamber 20. As shown in one possible embodiment in FIG. 4, top heaters 41 are preferably configured to generally conform to the shape and size of reaction chamber 20 for more uniform heating of the chamber and wafers W disposed therein.

Bottom heaters 42 may be a bulk-shaped electric resistance coils or elements and heater shape may be varied based on temperature requirements and shape and/or size of reaction chamber 20. Preferably, at least two bottom heaters 42 and more preferably at least three bottom heaters are provided to uniform CVD process temperatures in the bottom portion of the reaction chamber 20.

The heat output from each top and bottom heater 41, 42 is preferably controllable independently in a conventional manner similar to that described herein for sidewall heaters 40A-40F to allow the temperatures in the top and bottom heater zones of reaction chamber 20 to be fine tuned for optimum CVD processing and minimal variation in film thickness on the wafers.

As shown in one possible embodiment in FIG. 4, the sidewall heaters 40A-40F and top heaters 41 may be mounted on furnace housing 10 in the sidewall and top of the housing, respectively. Bottom heaters 42 may be configured and mounted onto bottom closure lid 26 or nearby. The bottom heaters may be movable or not to achieve their heating application.

The wafer film thickness deposition rates are directly proportional to CVD process temperature and reactant gas ratio. Accordingly, precise control of process temperatures within reaction chamber 20 to the maximum extent possible is desirable to minimize variation in film thicknesses deposited by CVD on an individual wafer and wafer-to-wafer basis. Optimally, uniform film thickness is required so that all dies fabricated on each wafer and all dies in the batch from wafer-to-wafer possess the same mechanical, electrical, and reliability properties. If variations in film thicknesses become too large, subsequent semiconductor processing steps as the dies undergo layer-by-layer fabrication through a series of further material deposition and removal steps may be adversely affected as well as the final die integrity. In addition, die failure rates may increase in subsequent wafer level and known good die testing.

Typical CVD process temperatures may vary from about 200-800 degrees C. depending on the type of material to be deposited on the wafers W. During the CVD process, reactant gas is introduced to reaction chamber 20 via the gas inlet connection 30, circulates through the reaction chamber and stack of multiple wafers, and exits the reaction chamber through gas outlet connection 31 as shown in FIG. 3.

Some reactant gases used in the CVD process need to be preheated before entering the reaction chamber depending on the particular gas used. The gases may be preheated by conventional means such as adding tape or collar-type heaters upon gas supply pipes. The tape heaters are preferably temperature controllable.

Film thickness deposition uniformity tests were conducted to compare the results of CVD processes using a semiconductor furnace having the new heater arrangement according to one embodiment of the present invention with existing conventional heater arrangements described herein. The tests were performed on the next generation 450 mm diameter wafers processed in batches within the semiconductor furnace. A silicon nitride (SiN) film, formed by the reaction of SiH2Cl2(or SiH4) and NH3 in reaction chamber 20, was deposited via CVD on the surface or face of each wafer. A target film thickness of 1650 A (Angstroms) was set for the tests. The results are shown in the table below:

| | | Existing Heater | New Heater Arrangement |
|---|---|---|---|
| | | Arrangement | (according to invention) |
| Within wafer film | % | 1.5-2.5% | 1.0-1.5% |
| thickness | Range | 50 A-80 A | 30 A-50 A |
| uniformity | | | |
| Wafer-to-wafer | % | <1% | <0.5% |
| film thickness | Range | <30 A | <16 A |
| uniformity | | | |

As shown in the table above, the SiN film thickness uniformity improved with a variance in thickness on each individual wafer decreasing to 1.0-1.5% or within a range of 30-50 A. Similarly, the SiN film thickness uniformity also improved on a wafer-to-wafer basis in the same batch with the variance in thickness between all wafers in the wafer boat decreasing to less than 0.5% or less than 16 A. This improvement is attributable to better uniformity in temperature both horizontally across each wafer in the wafer boat and vertically throughout the entire wafer stack from the improved heater arrangement, thereby resulting in more consistent material deposition rates throughout the CVD reaction chamber 20.

According to one aspect of the present invention, the temperature difference between a center portion of reaction chamber 20 (coinciding with the center of each wafer W when positioned in the chamber, see FIG. 3) and an edge or side portion of reaction chamber 20 (coinciding with the outer peripheral edge region of each wafer) is advantageously minimized. Heater arrangements according to embodiments of the present invention described herein can improve (i.e. reduce) the temperature difference to within 0.1° C. for a 450 mm wafer-sized chamber. However, in the conventional heater arrangement by contrast, the temperature difference will be around 0.5° C. for even for a smaller 300 mm wafer-sized chamber. If the 300 mm chamber is enlarged to accommodate a 450 mm wafer with the conventional heater arrangement (see, e.g. FIGS. 1 and 2), the temperature difference between the reaction chamber 20 center and edges or sides will be even larger than 0.5° C. It should be noted that a one degree C. temperature difference alone can adversely cause a variation of about 30 A for nitride film thickness. If the material deposition is intended for very thin film application to the wafer, a temperature difference within 0.1° C. will improve within wafer uniformity.

While the foregoing description and drawings represent preferred or exemplary embodiments of the present invention, it will be understood that various additions, modifications and substitutions may be made therein without departing from the spirit and scope and range of equivalents of the accompanying claims. In particular, it will be clear to those skilled in the art that the present invention may be embodied in other forms, structures, arrangements, proportions, sizes, and with other elements, materials, and components, without departing from the spirit or essential characteristics thereof. In addition, numerous variations in the methods/processes and/or control logic as applicable described herein may be made without departing from the spirit of the invention. One skilled in the art will further appreciate that the invention may be used with many modifications of structure, arrangement, proportions, sizes, materials, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims and equivalents thereof, and not limited to the foregoing description or embodiments. Rather, the appended claims should be construed broadly, to include other variants and embodiments of the invention, which may be made by those skilled in the art without departing from the scope and range of equivalents of the invention.

What is claimed is:

1. A semiconductor furnace comprising:
a vertical thermal reaction chamber having a height, a top, a bottom, a sidewall connecting the top and bottom, and an internal cavity for removably holding a batch of wafers, the chamber having a center portion and an edge portion;
a wafer boat positioned in the reaction chamber and being configured and adapted to hold a plurality of wafers in vertically-stacked relationship; and
a heating system comprising a plurality of heaters arranged and operative to heat the chamber, and including:
at least one top heater;
at least one bottom heater; and
a plurality of sidewall heaters spaced along the height of the reaction chamber, the sidewall heaters being arranged and controlled such that a temperature difference measured between the center portion of the chamber and the edge portion of the chamber is within 0.1 degrees C.

2. The semiconductor furnace of claim 1, wherein the sidewall heaters define a plurality of sidewall heater zones in the reaction chamber that are vertically spaced along the height of the reaction chamber, a temperature in each heater zone being controlled by a respective sidewall heater in each zone.

3. The semiconductor furnace of claim 2, wherein the sidewall heater zones are approximately evenly distributed along the height of the reaction chamber.

4. The semiconductor furnace of claim 1, wherein each sidewall has a heat output that is independently adjustable from the other sidewall heaters.

5. The semiconductor furnace of claim 1, wherein the sidewall heaters are electric resistance type coil elements.

6. The semiconductor furnace of claim 1, wherein the semiconductor furnace includes at least two top heaters and at least two bottom heaters.

7. The semiconductor furnace of claim 1, further comprising a wafer having a diameter of at least 450 mm and a surface, the wafer undergoing chemical vapor deposition processing in the reaction chamber, wherein a resultant film of material is deposited on the wafer having a maximum variation in thickness that is not more than 1.5%.

8. The semiconductor furnace of claim 1, further comprising a plurality of wafers each having a diameter of at least 450 mm and a surface, the wafers undergoing chemical vapor deposition processing in the reaction chamber, wherein a resultant film of material is deposited on each wafer having a maximum wafer-to-wafer variation in thickness that is less than 0.5%.

9. The semiconductor furnace of claim 1, wherein the top and bottom heaters are electric resistance type coil elements.

10. A combination semiconductor furnace and plurality of wafers processed therein, the combination comprising:
a vertical thermal reaction chamber having a height, a top, a bottom, a sidewall connecting the top and bottom, and an internal cavity for removably holding a batch of wafers;
a wafer boat positioned in the reaction chamber and holding a plurality of wafers in vertically-stacked relationship;
a heating system comprising a plurality of heaters arranged and operative to heat the chamber, and including:
at least one top heater;
at least one bottom heater; and
a plurality of sidewall heaters spaced along the height of the reaction chamber, the sidewall heaters being arranged such that at least one sidewall heater is provided for every ten vertically-stacked wafers to promote uniform thickness of film deposited on the wafers.

11. The combination of claim 10, wherein the resultant film of material deposited on each wafer has a maximum wafer-to-wafer variation in thickness that is less than 0.5%.

12. The combination of claim 10, wherein the sidewall heaters define a plurality of sidewall heater zones in the reaction chamber that are vertically spaced along the height of the reaction chamber, a temperature in each heater zone being controlled by a respective sidewall heater in each zone.

13. The combination of claim 10, wherein the sidewall heater zones are approximately evenly distributed along the height of the reaction chamber.

14. The combination of claim 10, wherein each sidewall has a heat output that is independently adjustable from the other sidewall heaters.

15. The combination of claim 10, wherein the sidewall heaters are electric resistance type coil elements.

16. A method for forming a thin layer of material on a semiconductor wafer comprising:
providing a semiconductor furnace including a vertical thermal reaction chamber having a height, a top, an open bottom, a sidewall connecting the top and bottom, and an internal cavity for removably holding a batch of wafers, the semiconductor furnace further including a heating system comprising at least one top heater, at least one bottom heater, and a plurality of sidewall heaters spaced along the height of the reaction chamber;
inserting a wafer boat holding a plurality of vertically-stacked wafers into the reaction chamber;
heating the reaction chamber with the heating system;
controlling a temperature difference measured between a center portion of the chamber and an edge portion of the chamber to within 0.1 degrees C.;
introducing a precursor reactant gas into the reaction chamber; and
forming a film of material on each wafer.

17. The method of claim 16, wherein the film of material formed on each wafer has a maximum wafer-to-wafer variation in thickness that is less than 0.5%.

18. The method of claim 16, wherein each wafer has a diameter of at least 450 mm.

19. The method of claim 16, wherein the film of material formed on each wafer has a maximum variation in thickness on each wafer that is not more than 1.5%.

20. The method of claim 16, wherein the semiconductor furnace includes at least two top heaters and at least two bottom heaters.
